(19) United States
(12) Patent Application Publication
(10) Pub. No.: US 2026/0144061 A1
(43) Pub. Date: May 21, 2026

(54) ELECTRONIC PACKAGE

(71) Applicant: SILICONWARE PRECISION INDUSTRIES CO., LTD., Taichung City (TW)

(72) Inventors: Chih-Hsien CHIU, Taichung City (TW); Chia-Chen CHIAO, Taichung City (TW)

(73) Assignee: SILICONWARE PRECISION INDUSTRIES CO., LTD., Taichung City (TW)

(21) Appl. No.: 19/097,407

(22) Filed: Apr. 1, 2025

(30) Foreign Application Priority Data
Nov. 20, 2024 (TW) 113144735

(51) Int. Cl. H01L 23/367; H01L 23/00; H01L 23/13; H01L 23/31; H01L 23/498; H01L 23/538; H01L 25/16

(52) U.S. Cl. CPC H10W 40/228; H10W 70/611; H10W 70/65; H10W 70/68; H10W 74/117; H10W 90/00; H10W 90/401; H10W 72/865; H10W 72/877; H10W 72/884; H10W 74/10; H10W 74/15; H10W 90/724; H10W 90/732; H10W 90/734; H10W 90/736; H10W 90/754

(57) ABSTRACT

An electronic package is mainly provided with an electronic component and a circuit structure on a carrier structure, and the circuit structure covers the electronic component and is formed with an opening, so that the electronic component is exposed from the opening. Moreover, a heat conductive member contacting the electronic component is accommodated in the opening, and a heat dissipation structure is disposed on the heat conductive member to provide a heat dissipation path for the electronic component via the heat conductive member and the heat dissipation structure.

### BACKGROUND

### 1. Technical Field

The present disclosure relates to a semiconductor packaging technology, and more particularly, to an electronic package having a heat dissipation structure.

### 2. Description of Related Art

With the evolution of the semiconductor packaging technology, different package types have been developed for the semiconductor devices. To improve electrical function and save packaging space, the industry has developed a package type that stacks multiple package structures to form a package on package (POP) structure. This package type can take advantage of the heterogeneous integration characteristics of System in Package (SiP), and can integrate electronic components, such as: memories, central processing units, graphics processors, image application processors, etc., with different functions via stacking design to achieve system integration, and is suitable for various light, thin, short and small electronic products.

FIG. 1 is a schematic cross-sectional view of a conventional package stack structure 1. The package stack structure 1 includes a first semiconductor chip 10, a first package substrate 11, a second package substrate 12, a plurality of solder balls 13, a second semiconductor chip 14 and an encapsulating compound 15. The first package substrate 11 has a core layer 110 and a plurality of circuit layers 111, and the second package substrate 12 has a core layer 120 and a plurality of circuit layers 121. The first semiconductor chip 10 is disposed on the first package substrate 11 in a flip-chip manner, and the second semiconductor chip 14 is also disposed on the second package substrate 12 in a flip-chip manner. The solder balls 13 are used to connect and electrically couple the first package substrate 11 and the second package substrate 12. The encapsulating compound 15 covers the solder balls 13 and the first semiconductor chip 10. An underfill 16 can also be selectively formed between the first semiconductor chip 10 and the first package substrate 11.

However, the first semiconductor chip 10 is covered in the encapsulating compound 15. If the heat generated during the operation of the first semiconductor chip 10 cannot be effectively dissipated, overheating or even damage would occur.

Therefore, how to overcome the above-mentioned drawbacks of the prior art has become an urgent issue to be solved.

### SUMMARY

In view of the various deficiencies of the prior art, the present disclosure provides an electronic package, which comprises: a carrier structure having a first side and a second side opposite to the first side; an electronic component disposed on the first side of the carrier structure and electrically connected to the carrier structure; a circuit structure disposed on the first side of the carrier structure and electrically connected to the carrier structure so that the electronic component is covered by the circuit structure, wherein the circuit structure is formed with an opening to expose at least a portion of the electronic component; a heat conductive member disposed on the electronic component and accommodated in the opening; and a heat dissipation structure disposed on the heat conductive member.

In the aforementioned electronic package, the electronic component is disposed on the carrier structure via a plurality of conductive bumps, and an underfill covering the plurality of conductive bumps is formed between the electronic component and the carrier structure.

In the aforementioned electronic package, the circuit structure is attached to the carrier structure via a plurality of conductive members. The plurality of conductive members are copper core balls, metal pillars, solder balls or wires.

In the aforementioned electronic package, the heat conductive member is a dummy silicon chip.

In the aforementioned electronic package, the electronic package further comprises an encapsulant covering the electronic component, the circuit structure and the heat conductive member.

In the aforementioned electronic package, the heat dissipation structure includes a metal layer formed on the heat conductive member, an insulating layer covering a portion of the metal layer, and a plurality of metal bumps formed on the metal layer.

In the aforementioned electronic package, the heat dissipation structure includes a metal layer formed on the heat conductive member, an insulating layer covering a portion of the metal layer, and a plurality of under bump metallization layers formed on the metal layer and the insulating layer.

In the aforementioned electronic package, the heat dissipation structure includes a metal layer formed on the heat conductive member, an insulating layer covering a portion of the metal layer, a plurality of under bump metallization layers formed on the metal layer and the insulating layer, and a plurality of metal bumps formed on the plurality of under bump metallization layers.

In the aforementioned electronic package, the heat dissipation structure is in a shape of a fin and is integrally formed with the heat conductive member.

In the aforementioned electronic package, the electronic package further comprises a package module disposed on the circuit structure.

In the aforementioned electronic package, a plurality of the heat conductive members are disposed on the electronic component, and the heat dissipation structure is disposed on each of the heat conductive members.

In the aforementioned electronic package, a plurality of electronic components are disposed on the carrier structure, the heat conductive member is disposed on each of the plurality of electronic components, and the heat dissipation structure is disposed on each of the heat conductive members.

In the aforementioned electronic package, the circuit structure is in a form of an interposer, and a plurality of conductive through holes are formed therein.

As can be seen from the above, in the electronic package of the present disclosure, the circuit structure formed with an opening is disposed on the carrier structure, so that the electronic component disposed on the carrier structure is exposed from the opening of the circuit structure. Moreover, a heat conductive member contacting the electronic component is accommodated in the opening, and a heat dissipation structure is disposed on the heat conductive member to improve the heat dissipation effect of the electronic component.

### BRIEF DESCRIPTION OF THE DRAWINGS

FIG. 1 is a schematic cross-sectional view of a conventional package stack structure.

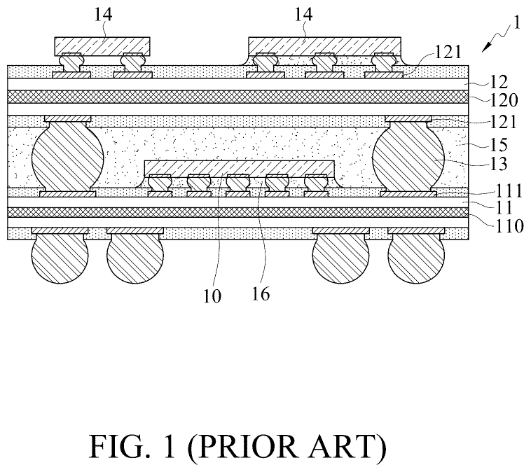

FIG. 2A and FIG. 2B are schematic cross-sectional and top views of an electronic package according to a first embodiment of the present disclosure.

FIG. 3A and FIG. 3B are schematic cross-sectional and top views of an electronic package according to a second embodiment of the present disclosure.

FIG. 4 is a schematic cross-sectional view of an electronic package according to a third embodiment of the present disclosure.

FIG. 5 is a schematic cross-sectional view of an electronic package according to a fourth embodiment of the present disclosure.

FIG. 6 is a schematic cross-sectional view of an electronic package according to a fifth embodiment of the present disclosure.

FIG. 7A and FIG. 7B are schematic cross-sectional and top views of an electronic package according to a sixth embodiment of the present disclosure.

FIG. 8 is a schematic cross-sectional view of an electronic package according to a seventh embodiment of the present disclosure.

FIG. 9 is a schematic cross-sectional view of an electronic package according to an eighth embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

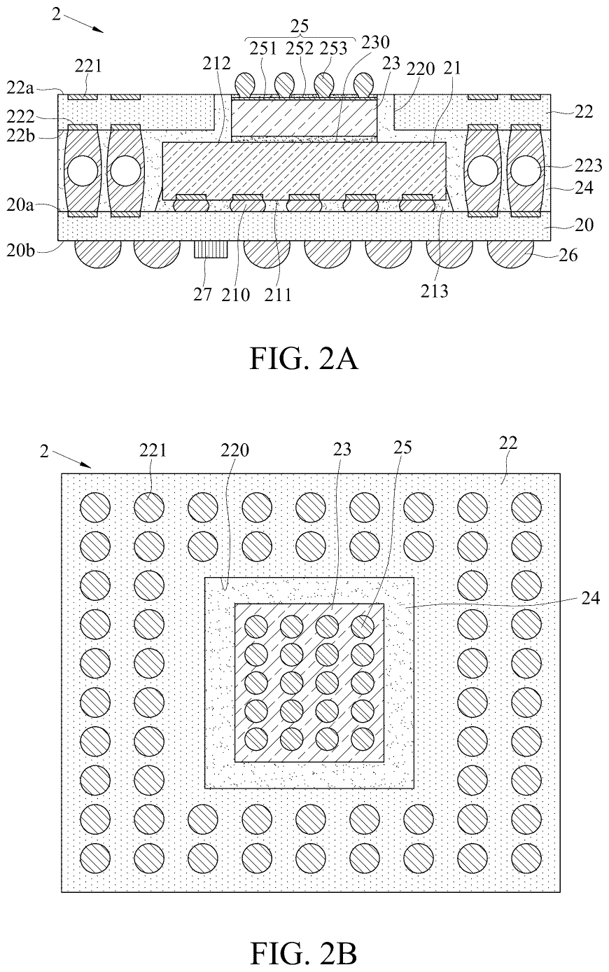

FIG. 2A and FIG. 2B are schematic cross-sectional and top views of an electronic package 2 according to a first embodiment of the present disclosure.

As shown in the figure, the electronic package 2 includes: a carrier structure 20 having a first side 20a and a second side 20b opposite to the first side 20a; an electronic component 21 disposed on the first side 20a of the carrier structure 20 and electrically connected to the carrier structure 20; a circuit structure 22 disposed on the first side 20a of the carrier structure 20 and electrically connected to the carrier structure 20, and covering the electronic component 21; a heat conductive member 23 disposed on the electronic component 21; and a heat dissipation structure 25 disposed on the heat conductive member 23.

The carrier structure 20 is, for example, a package substrate having a core layer or a coreless package substrate, which has an insulating base and a wiring layer bonded to the insulating base. The carrier structure 20 has a first side 20a and a second side 20b opposite to the first side 20a.

The electronic component 21 can be an active component, a passive component, or a combination of the active component and the passive component. The active component is, for example, a semiconductor chip, and the passive component is, for example, a resistor, a capacitor, and an inductor. In one embodiment, the electronic component 21 is a semiconductor chip and has an active surface 211 and an inactive surface 212 opposite to the active surface 211. The electronic component 21 is disposed on the first side 20a of the carrier structure 20 in a flip-chip manner via a plurality of conductive bumps 210 of solder material and is electrically connected to the wiring layer, and an underfill 213 is formed between the electronic component 21 and the carrier structure 20 to cover the plurality of conductive bumps 210. However, the ways in which the electronic component 21 can be electrically connected to the carrier structure 20 are various and not limited to as such.

In one embodiment, the circuit structure 22 has a first surface 22a and a second surface 22b opposite to the first surface 22a, and has at least one opening 220 penetrating the first surface 22a and the second surface 22b. A plurality of first conductive contacts 221 and a plurality of second conductive contacts 222 are respectively formed on the first surface 22a and the second surface 22b, and a circuit layer is formed connecting the first surface 22a and the second surface 22b, so that the first conductive contacts 221 on the first surface 22a and the second conductive contacts 222 on the second surface 22b are allowed to be electrically connected to each other via the circuit layer. The first conductive contacts 221 and the second conductive contacts 222 are, for example, soldering pads. In addition, the circuit structure 22 may be a package substrate having a core layer or a coreless package substrate, or may be a silicon interposer.

The circuit structure 22 can be attached and electrically connected to the first side 20a of the carrier structure 20 via a plurality of conductive members 223 One end of each of the conductive members 223 is connected to one of the second conductive contacts 222 of the circuit structure 22, and the other end of each of the conductive members 223 is connected to the carrier structure 20. The position of the electronic component 21 corresponds to the position of the opening 220, so that at least a portion of the inactive surface 212 of the electronic component 21 is exposed from the opening 220. In one embodiment, each of the conductive members 223 can be a copper core ball to effectively maintain the distance between the circuit structure 22 and the carrier structure 20. In other embodiments, each of the conductive members 223 may be a metal pillar (copper pillar), a solder ball or a wire.

The heat conductive member 23 can be attached to the inactive surface 212 of the electronic component 21 exposed from the opening 220 via a heat conductive adhesive 230. In one embodiment, the heat conductive member 23 is, for example, a dummy silicon chip.

In addition, an encapsulant 24 covering the electronic component 21, the circuit structure 22, the heat conductive member 23, and the conductive members 223 is formed on the carrier structure 20, and a portion of the encapsulant 24 (or even a portion of the heat conductive member 23) can be removed via a thinning operation, such as grinding, so that the heat conductive member 23 is exposed from the encapsulant 24.

The heat dissipation structure 25 is disposed on the heat conductive member 23 and is exposed from the encapsulant 24. In one embodiment, the heat dissipation structure 25 includes a metal layer 251 formed on the heat conductive member 23, an insulating layer 252 covering a portion of the metal layer 251, and a plurality of metal bumps 253 formed on the metal layer 251. The metal layer 251 and the metal bumps 253 are made of, for example, metal copper, and the insulating layer 252 is made of, for example, polyimide (PI).

In addition, a plurality of conductive elements 26 such as solder balls and a passive module 27 can be disposed on the second side 20b of the carrier structure 20, thereby producing the electronic package 2 of the present disclosure.

Therefore, in the electronic package 2 of the present disclosure, the circuit structure 22 formed with an opening 220 is disposed on the carrier structure 20 provided with the electronic component 21, so that the electronic component 21 is exposed from the opening 220, a heat conductive member 23 contacting the electronic component is accommodated in the opening, and a heat dissipation structure 25 including the plurality of metal bumps 253 is formed on the heat conductive member 23, thereby the electronic component 21 embedded in the encapsulant 24 can effectively dissipate the heat generated during operation via a heat dissipation path provided by the heat conductive member 23 and the heat dissipation structure 25.

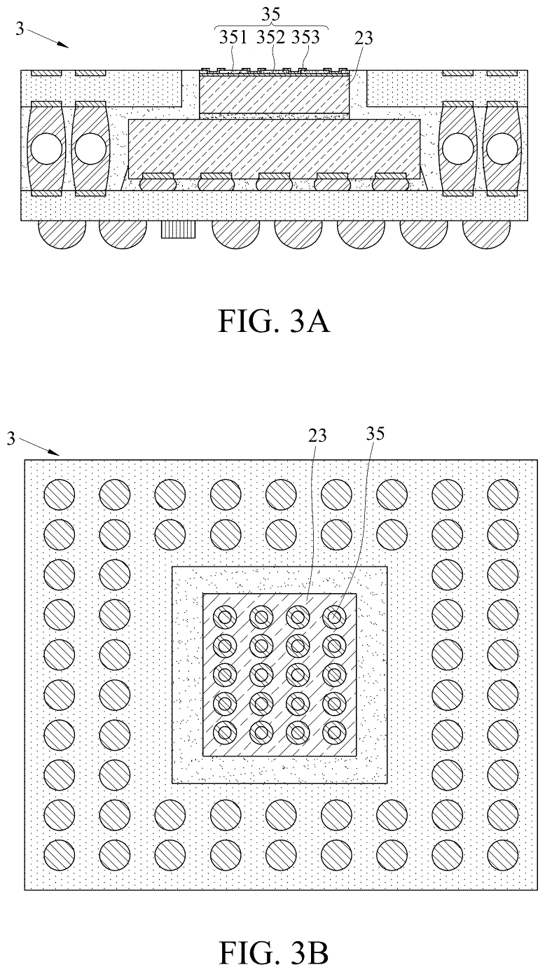

Please refer to FIG. 3A and FIG. 3B, which are schematic cross-sectional and top views of an electronic package according to a second embodiment of the present disclosure. The difference between this embodiment and the previous embodiments lies in the form and scope of the heat dissipation structure. The other structures are basically the same, so the similarities will not be restated again.

In an electronic package 3, a heat dissipation structure 35 includes a metal layer 351 formed on the heat conductive member 23, an insulating layer 352 covering a portion of the metal layer 351, and a plurality of under bump metallization (UBM) layers 353 formed on the metal layer 251 and the insulating layer 352.

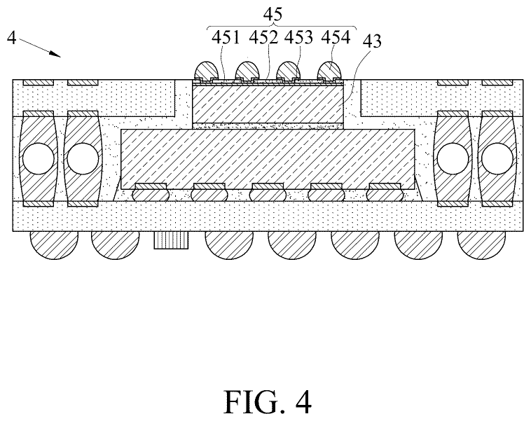

Please refer to FIG. 4, which is a schematic cross-sectional view of an electronic package according to a third embodiment of the present disclosure. The difference between this embodiment and the previous embodiments lies in the form and scope of the heat dissipation structure. The other structures are basically the same, so the similarities will not be restated again.

In an electronic package 4, a heat dissipation structure 45 includes a metal layer 451 formed on a heat conductive member 43, an insulating layer 452 covering a portion of the metal layer 451, a plurality of under bump metallization (UBM) layers 453 formed on the metal layer 451 and the insulating layer 452, and a plurality of metal bumps 454 formed on the under bump metallization layers 453.

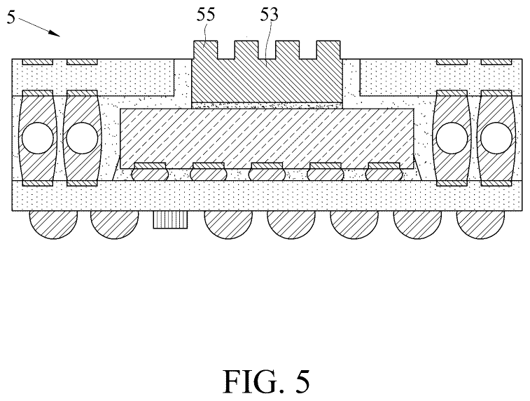

Please refer to FIG. 5, which is a schematic cross-sectional view of an electronic package according to a fourth embodiment of the present disclosure. The difference between this embodiment and the previous embodiments lies in the form and scope of the heat dissipation structure. The other structures are basically the same, so the similarities will not be restated again.

In an electronic package 5, a heat dissipation structure 55 is in the shape of a fin and is integrally formed with a heat conductive member 53.

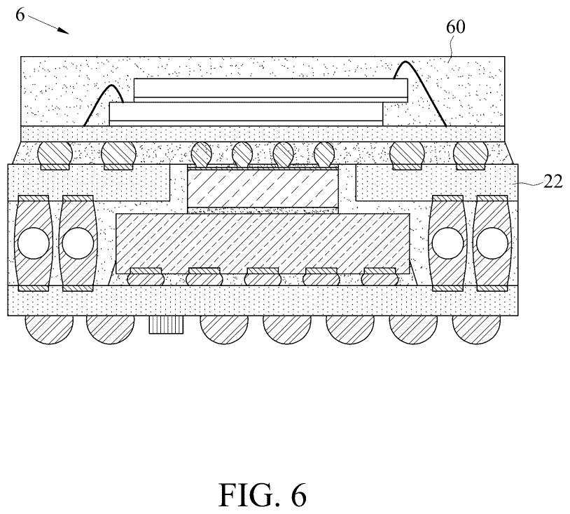

Please refer to FIG. 6, which is a schematic cross-sectional view of an electronic package according to a fifth embodiment of the present disclosure. An electronic package 6 in this embodiment is basically the same as the previous embodiments. The main difference is that a package module 60 (such as a memory module) can be disposed on the circuit structure 22 to form a package stack structure.

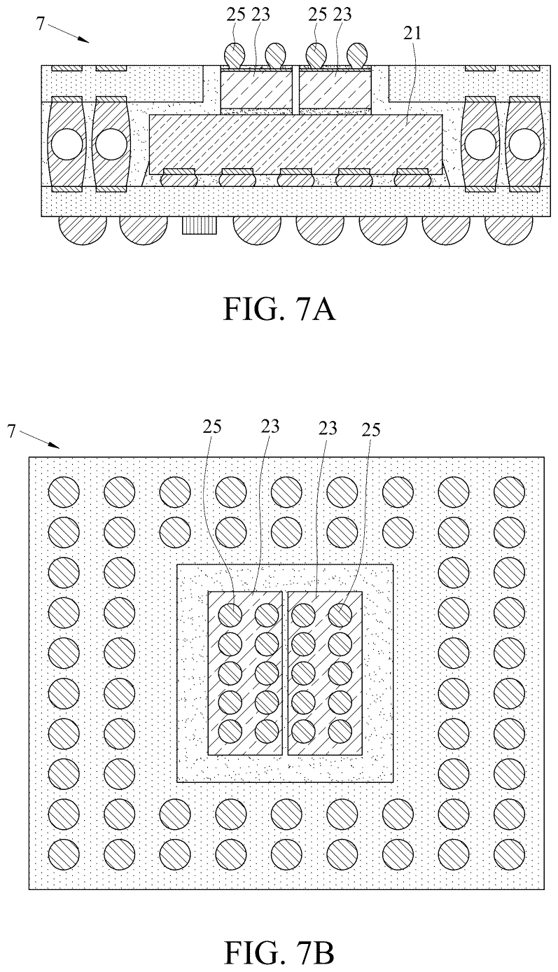

Please refer to FIG. 7A and FIG. 7B, which are schematic cross-sectional and top views of an electronic package according to a sixth embodiment of the present disclosure. An electronic package 7 in this embodiment is basically the same as the previous embodiments. The main difference is that a plurality of heat conductive members 23 can be disposed on a single electronic component 21, and at least one heat dissipation structure 25 can be disposed on each heat conductive member 23 to provide multiple heat dissipation paths for the electronic component 21.

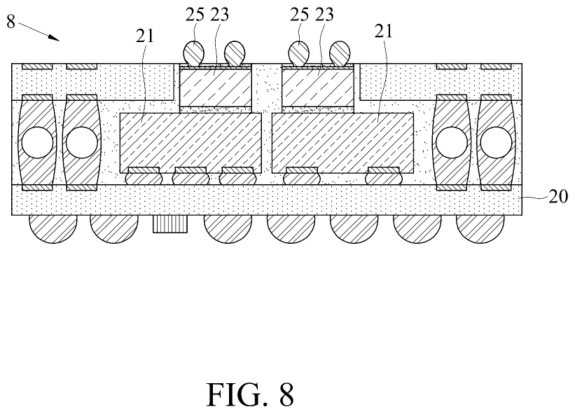

Please refer to FIG. 8, which is a schematic cross-sectional view of an electronic package according to a seventh embodiment of the present disclosure. An electronic package 8 in this embodiment is basically the same as the previous embodiments. The main difference is that a plurality of electronic components 21 can be disposed on the carrier structure 20, at least one heat conductive member 23 is disposed on each of the electronic components 21, and at least one heat dissipation structure 25 is disposed on each of the heat conductive members, thereby providing a good heat dissipation path for each of the electronic components 21.

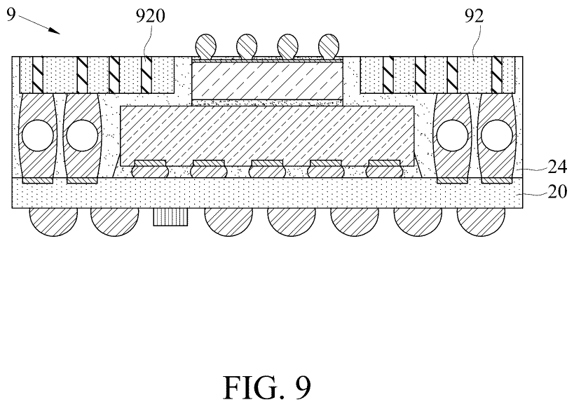

Please refer to FIG. 9, which is a schematic cross-sectional view of an electronic package according to an eighth embodiment of the present disclosure. An electronic package 9 in this embodiment is basically the same as the previous embodiments. The main difference is that a circuit structure 92 can be in the form of an interposer, so that a plurality of conductive through holes 920 are formed in the circuit structure 92, wherein a planar size of the circuit structure 92 is smaller than a planar size of the carrier structure 20, so that the encapsulant 24 covers a side of the circuit structure 92.

To sum up, in the electronic package of the present disclosure, the circuit structure having an opening is disposed on the carrier structure, so that the electronic component disposed on the carrier structure is exposed from the opening of the circuit structure. Moreover, a heat conductive member contacting the electronic component is accommodated in the opening, and a heat dissipation structure is disposed on the heat conductive member to improve the heat dissipation effect of the electronic component. Meanwhile, the electronic package of the present disclosure can solve the existing technical problems in the industry without adding new development processes and materials or purchasing machines, so that there is no large additional cost.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first side and a second side opposite to the first side;
an electronic component disposed on the first side of the carrier structure and electrically connected to the carrier structure;
a circuit structure disposed on the first side of the carrier structure and electrically connected to the carrier structure so that the electronic component is covered by the circuit structure, wherein the circuit structure is formed with an opening to expose at least a portion of the electronic component;
a heat conductive member disposed on the electronic component and accommodated in the opening; and
a heat dissipation structure disposed on the heat conductive member.

2. The electronic package of claim 1, wherein the electronic component is disposed on the carrier structure via a plurality of conductive bumps, and an underfill covering the plurality of conductive bumps is formed between the electronic component and the carrier structure.

3. The electronic package of claim 1, wherein the circuit structure is attached to the carrier structure via a plurality of conductive members.

4. The electronic package of claim 3, wherein the plurality of conductive members are copper core balls, metal pillars, solder balls or wires.

5. The electronic package of claim 1, wherein the heat conductive member is a dummy silicon chip.

6. The electronic package of claim 1, further comprising an encapsulant covering the electronic component, the circuit structure and the heat conductive member.

7. The electronic structure of claim 1, wherein the heat dissipation structure includes a metal layer formed on the heat conductive member, an insulating layer covering a portion of the metal layer, and a plurality of metal bumps formed on the metal layer.

8. The electronic structure of claim 1, wherein the heat dissipation structure includes a metal layer formed on the heat conductive member, an insulating layer covering a portion of the metal layer, and a plurality of under bump metallization layers formed on the metal layer and the insulating layer.

9. The electronic package of claim 1, wherein the heat dissipation structure includes a metal layer formed on the heat conductive member, an insulating layer covering a portion of the metal layer, a plurality of under bump metallization layers formed on the metal layer and the insulating layer, and a plurality of metal bumps formed on the plurality of under bump metallization layers.

10. The electronic package of claim 1, wherein the heat dissipation structure is in a shape of a fin and is integrally formed with the heat conductive member.

11. The electronic package of claim 1, further comprising a package module disposed on the circuit structure.

12. The electronic package of claim 1, wherein a plurality of the heat conductive members are disposed on the electronic component, and the heat dissipation structure is disposed on each of the heat conductive members.

13. The electronic package of claim 1, wherein a plurality of electronic components are disposed on the carrier structure, the heat conductive member is disposed on each of the plurality of electronic components, and the heat dissipation structure is disposed on each of the heat conductive members.

14. The electronic package of claim 1, wherein the circuit structure is in a form of an interposer, and a plurality of conductive through holes are formed therein.
